(19) United States
(12) Patent Application Publication
(10) Pub. No.: US 2012/0238075 A1
(43) Pub. Date: Sep. 20, 2012

(54) COATING APPARATUS AND COATING METHOD

(75) Inventors: Hidenori Miyamoto, Kawasaki-shi (JP); Tsutomu Sahoda, Kawasaki-shi (JP)

(73) Assignee: TOKYO OHKA KOGYO CO., LTD., Kawasaki-shi (JP)

(21) Appl. No.: 13/412,910

(22) Filed: Mar. 6, 2012

Related U.S. Application Data
(60) Provisional application No. 61/450,875, filed on Mar. 9, 2011.

(51) Int. Cl. H01L 21/208; B05B 1/02; B05B 15/04

(52) U.S. Cl. 438/478; 118/300; 118/712; 118/602; 257/E21.114

(57) ABSTRACT

A coating apparatus including a coating part which applies a liquid material containing an oxidizable metal and a solvent to a substrate; a chamber having a coating space in which the coating part applies the liquid material to the substrate and a transport space into which the substrate is transported; and a removal part which removes the liquid material from the atmosphere inside the chamber when a concentration of the solvent in the atmosphere inside the chamber exceeds a threshold value.

Priority is claimed on Provisional Application No. 61/450,875, filed on Mar. 9, 2011, the content of which is incorporated herein by reference.

### FIELD OF THE INVENTION

The present invention relates to a coating apparatus and a coating method.

### DESCRIPTION OF THE RELATED ART

A CIGS solar cell or a CZTS solar cell formed by semiconductor materials including a metal such as Cu, Ge, Sn, Pb, Sb, Bi, Ga, In, Ti, Zn, and a combination thereof, and a chalcogen element such as S, Se, Te, and a combination thereof has been attracting attention as a solar cell having high conversion efficiency (for example, see Patent Documents 1 to 3). For example, a CIGS solar cell has a structure in which a film including four types of semiconductor materials, namely, Cu, In, Ga, and Se is used as a light absorbing layer (photoelectric conversion layer). Further, for example, a CZTS solar cell has a structure in which a film including four types of semiconductor materials, namely, Cu, Zn, Sn, and Se is used as a light absorbing layer (photoelectric conversion layer). In such solar cells, a configuration is known in which a back electrode made of molybdenum is provided on a substrate such a glass, and the aforementioned light absorbing layer is provided on the back electrode.

In a CIGS solar cell or a CZTS solar cell, since it is possible to reduce the thickness of the light absorbing layer compared to a conventional solar cell, it is easy to install the CIGS solar cell on a curved surface and to transport the CIGS solar cell. For this reason, it is expected that CIGS solar cells can be used in various application fields as a high-performance, flexible solar cell. As a method of forming the light absorbing layer, a method of forming the light absorbing layer through depositing or sputtering is conventionally known (for example, see Patent Documents 2 to 5).

### DOCUMENTS OF RELATED ART

### Patent Documents

[Patent Document 1] Japanese Unexamined Patent Application, First Publication No. Hei 11-340482
[Patent Document 2] Japanese Unexamined Patent Application, First Publication No. 2005-51224
[Patent Document 3] Published Japanese Translation No. 2009-537997 of the PCT International Publication
[Patent Document 4] Japanese Unexamined Patent Application, First Publication No. Hei 1-231313
[Patent Document 5] Japanese Unexamined Patent Application, First Publication No. Hei 11-273783

### SUMMARY OF THE INVENTION

In contrast, as the method of forming the light absorbing layer, the present inventors propose a method of coating the semiconductor materials in the form of a liquid material on a substrate. In such a method of forming the light absorbing layer by coating the semiconductor materials in the form of a liquid material, the following problems arise.

In the case of coating a liquid material, when the concentration of the solvent becomes high in the atmosphere of the coating environment, there is a possibility that the ambient apparatuses and environment are affected. This problem is not limited to the case of forming a semiconductor film of a CIGS solar cell, but may generally arise in a coating operation using a liquid material including the oxidizable metals.

The present invention takes the above circumstances into consideration, with an object of providing a coating apparatus and a coating method capable of suppressing change in the coating environment.

A coating apparatus according to a first aspect of the present invention includes a coating part which applies a liquid material containing an oxidizable metal and a solvent to a substrate; a chamber having a coating space in which the coating part applies the liquid material to the substrate and a transport space into which the substrate is transported; and a removal part which removes the liquid material from the atmosphere inside the chamber when a concentration of the solvent in the atmosphere inside the chamber exceeds a first threshold value.

In this case, by virtue of providing a removal part which removes the liquid material from the atmosphere inside the chamber when a concentration of the solvent in the atmosphere inside the chamber exceeds a first threshold value, increase in the concentration of the solvent in the atmosphere can be suppressed. As a result, change in the coating environment can be suppressed.

The coating apparatus may further include a detection part which detects the concentration of the solvent in the atmosphere inside the chamber.

In this case, by virtue of providing a detection part which detects the concentration of the solvent in the atmosphere inside the chamber, the detection results of the detection part can be used to compare with the threshold value.

In the coating apparatus, the removal part may include a recovery part which recovers the removed liquid material.

In this case, by virtue of the removed liquid material being recovered by the recovery part, the removed liquid material can be prevented from being wasted.

In the coating apparatus, the recovery part may include a circulation path which returns the removed liquid material into the chamber.

In this case, by virtue of the removed liquid material being returned into the chamber via the circulation path, the recovered liquid material can be reused.

In the coating apparatus, the removal part may include a discharge part which discharges the solvent in the atmosphere inside the chamber.

In this case, by virtue of the solvent in the atmosphere inside the chamber being discharged by the discharge part, the concentration of the solvent in the atmosphere inside the chamber can be reduced.

In the coating apparatus, the removal part may include a control device which controls the removal part to wait removing the liquid material until the coating part finishes treating the substrate having the liquid material applied thereto when the concentration of the solvent in the atmosphere inside the chamber exceeds the first threshold value.

In this case, it becomes possible to avoid the treatment of the substrate being stopped in the course of the treatment. In this manner, a waste of the substrate can be avoided.

In the coating apparatus, the control device may stop the substrate which has finished being treated from being transported to the coating part.

In this case, by virtue of stopping the substrate which has finished being treated from being transported to the coating part, the substrate can be prevented from being affected by the change in the coating environment. As a result, decrease in the yield can be avoided. Further, the concentration of the solvent in the atmosphere inside the chamber can be reduced.

In the coating apparatus, the control device may control the removal part to wait removing the liquid material until the coating part is moved to a maintenance position after the substrate has been finished being treated.

In this case, by controlling the removal part to wait removing the liquid material until the coating part is moved to a maintenance position after the substrate has been finished being treated, for example, even when dripping of the liquid material occurs in the coating part after the treatment, adhesion of the liquid material on the treatment position of the substrate can be prevented, and the liquid material can be reliably recovered.

In the coating apparatus, the control device may stop at least all treatments associated with coating of the liquid material when the concentration of the solvent in the atmosphere inside the chamber exceeds a second threshold value which is larger than the first threshold value.

When the concentration of the solvent in the atmosphere inside the chamber exceeds a second threshold value which is larger than the first threshold value, it is sometimes preferable to perform an emergency stop of the apparatus itself prior to removing the liquid material. In the above configuration, when the concentration of the solvent in the atmosphere inside the chamber exceeds a second threshold value which is larger than the first threshold value, the apparatus itself will be stopped prior to removing the liquid material.

In the coating apparatus, the coating part may include a slit nozzle which ejects the liquid material.

In this case, change in the coating environment around the slit nozzle can be suppressed. As a result, change in the ejection state of the slit nozzle can be suppressed, and the ejection can be stably performed.

A coating method according to a second aspect of the present invention includes a coating step in which a liquid material containing an oxidizable metal and a solvent is applied to a substrate; and a removing step in which the liquid material is removed from the atmosphere inside a chamber having a coating space where the coating part applies the liquid material to the substrate and a transport space into which the substrate is transported when a concentration of the solvent in the atmosphere inside the chamber exceeds a first threshold value.

In this case, by virtue of removing the liquid material from the atmosphere inside the chamber where the liquid material is applied when a concentration of the solvent in the atmosphere inside the chamber exceeds a first threshold value, increase in the concentration of the solvent in the atmosphere can be suppressed. As a result, change in the coating environment can be suppressed.

The coating method may further include a detection step in which the concentration of the solvent in the atmosphere inside the chamber is detected.

In this case, by virtue of detecting the concentration of the solvent in the atmosphere inside the chamber, the detection results can be used to compare with the first threshold value.

In the coating method, the removing step may include a recovering step in which the removed liquid material is recovered.

In this case, by virtue of the removed liquid material being recovered, the removed liquid material can be prevented from being wasted.

In the coating method, the recovering step may include a returning step in which the removed liquid material is returned into the chamber.

In this case, by virtue of the removed liquid material being returned into the chamber, the recovered liquid material can be reused.

In the coating method, the removing step may include a discharging step in which the solvent in the atmosphere inside the chamber is discharged.

In this case, by virtue of the solvent in the atmosphere inside the chamber being discharged, the concentration of the solvent in the atmosphere inside the chamber can be reduced.

In the coating method, the removing step may wait removing the liquid material until the coating part finishes treating the substrate having the liquid material applied thereto when the concentration of the solvent in the atmosphere inside the chamber exceeds the first threshold value.

In this case, it becomes possible to avoid the treatment of the substrate being stopped in the course of the treatment. In this manner, a waste of the substrate can be avoided.

In the coating method, the removing step may include stopping the substrate which has finished being treated from being transported to the coating part.

In this case, by virtue of stopping the substrate which has finished being treated from being transported to the coating part, the substrate can be prevented from being affected by the change in the coating environment. As a result, decrease in the yield can be avoided. Further, the concentration of the solvent in the atmosphere inside the chamber can be reduced.

In the coating method, the removing step may be performed after the coating part is moved to a maintenance position after the substrate has been finished being treated.

In this case, by performing the removing step after the coating part is moved to a maintenance position after the substrate has been finished being treated, for example, even when leaking of the liquid material occurs in the coating part after the treatment, adhesion of the liquid material on the treatment position of the substrate can be prevented, and the liquid material can be reliably recovered.

In the coating method, the removing step may include stopping at least all treatments associated with coating of the liquid material when the concentration of the solvent in the atmosphere inside the chamber exceeds a second threshold value which is larger than the first threshold value.

When the concentration of the solvent in the atmosphere inside the chamber exceeds a second threshold value which is larger than the first threshold value, it is sometimes preferable to perform an emergency stop of the apparatus itself prior to removing the liquid material. In the above configuration, when the concentration of the solvent in the atmosphere inside the chamber exceeds a second threshold value which is larger than the first threshold value, the apparatus itself will be stopped prior to removing the liquid material.

In the coating method, the coating step may include ejecting the liquid material from a slit nozzle.

In this case, change in the coating environment around the slit nozzle can be suppressed. As a result, change in the ejection state of the slit nozzle can be suppressed, and the ejection can be stably performed.

According to the embodiments of the present invention, change in the coating environment can be suppressed.

### BRIEF DESCRIPTION OF THE DRAWINGS

FIG. 1 is a diagram showing an entire configuration of a coating apparatus according to one embodiment of the present invention.

FIG. 2 is a diagram showing an entire configuration of a coating apparatus according to the present embodiment.

FIG. 3 is a diagram showing a configuration of a nozzle according to the present embodiment.

FIG. 4 is a diagram showing a configuration of a nozzle according to the present embodiment.

FIG. 5 is a diagram showing a configuration of part of a coating apparatus according to the present embodiment.

FIG. 6 is a diagram showing a configuration of a vacuum drying part according to the present embodiment.

FIG. 7 is a diagram showing a configuration of part of a baking part according to the present embodiment.

FIG. 8 is a diagram showing a step in a coating treatment performed by a coating apparatus according to the present embodiment.

FIG. 9 is a diagram showing a step in a coating treatment performed by a coating apparatus according to the present embodiment.

FIG. 10 is a diagram showing a step in a coating treatment performed by a coating apparatus according to the present embodiment.

FIG. 11 is a diagram showing a step in a coating treatment performed by a coating apparatus according to the present embodiment.

FIG. 12 is a diagram showing a step in a coating treatment performed by a coating apparatus according to the present embodiment.

FIG. 13 is a diagram showing a step in a baking treatment performed by a coating apparatus according to the present embodiment.

FIG. 14 is a diagram showing a step in a baking treatment performed by a coating apparatus according to the present embodiment.

FIG. 15 is a diagram showing a step in a baking treatment performed by a coating apparatus according to the present embodiment.

FIG. 16 is a diagram showing a step in a baking treatment performed by a coating apparatus according to the present embodiment.

FIG. 17 is a diagram showing a step in a baking treatment performed by a coating apparatus according to the present embodiment.

FIG. 18 is a diagram showing a step in a removing treatment performed by a coating apparatus according to the present embodiment.

### MODE FOR CARRYING OUT THE INVENTION

Hereinafter, one embodiment of the present invention will be described with reference to the accompanying drawings.

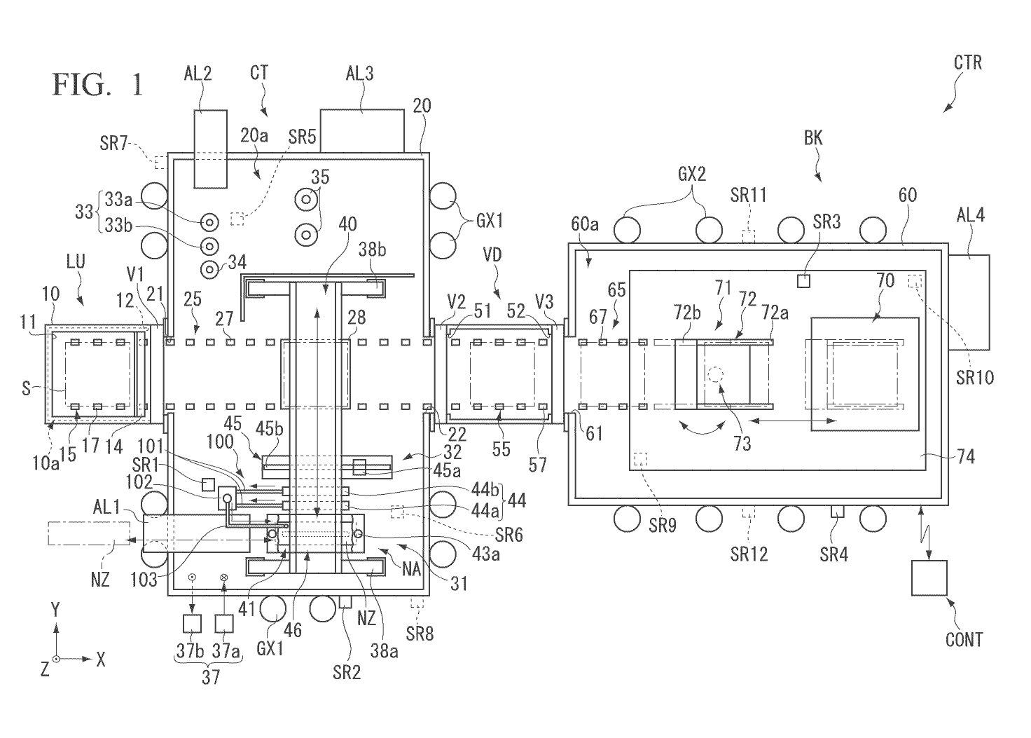

FIG. 1 is a schematic diagram showing a configuration of a coating apparatus CTR according to one embodiment of the present invention.

As shown in FIG. 1, the coating apparatus CTR is an apparatus which applies a liquid material to a substrate S. The coating apparatus CTR includes a substrate loading/unloading part LU, a coating part CT, a vacuum drying part VD, a baking part BK and a control part CONT. The coating apparatus CTR is used, for example, by being disposed on a floor FL in a factory. The coating apparatus may have a configuration in which the coating apparatus is accommodated in one room, or a configuration in which the coating apparatus is divisionally accommodated in a plurality of rooms. In the coating apparatus CTR, the substrate loading/unloading part LU, the coating part CT, the vacuum drying part VD and the baking part BK are arranged in this order in one direction. With respect to the configuration of the coating apparatus CTR, it is not particularly limited that the substrate loading/unloading part LU, the coating part CT, the vacuum drying part VD and the baking part BK are arranged in this order in one direction. For example, the substrate loading/unloading part LU may be divided into a substrate loading part (not shown) and a substrate unloading part (not shown). Further, the vacuum drying part VD may be omitted. Needless to say, the aforementioned parts may not be arranged in one direction, and a configuration may be employed in which the aforementioned parts are arranged to be stacked in a vertical or horizontal direction with a robot (not shown) disposed at a central position.

In the respective drawings as below, upon describing the configuration of a substrate treating apparatus according to the present embodiment, for the purpose of simple marking, an XYZ coordinate system is used to describe the directions in the drawings. In the XYZ coordinate system, the plane parallel to the floor is regarded as the XY plane. On the XY plane, the direction in which the components of the coating apparatus CTR (the substrate loading/unloading part LU, the coating part CT, the vacuum drying part VD and the baking part BK) are arranged is marked as the X direction, and the direction perpendicular to the X direction on the XY plane is marked as the Y direction. The direction perpendicular to the XY plane is marked as the Z direction. In the X, Y, and Z directions, the arrow direction in the drawing is the +direction, and the opposite direction of the arrow direction is the −direction.

In this embodiment, as the substrate S, for example, a plate-shaped member made of glass, resin, or the like may be used. Further, in this embodiment, molybdenum is sputtered on the substrate S as a back electrode. Needless to say, any other electroconductive material may be used as a back electrode. Explanation will be given below, taking an example of a substrate having a size of 330 mm×330 mm as viewed in the Z direction. The size of the substrate is not limited to 330 mm×330 mm. For example, as the substrate S, a substrate having a size of 125 mm×125 mm may be used, or a substrate having a size of 1 m×1 m may be used. Needless to say, a substrate having a size larger than the aforementioned sizes or a substrate having a size smaller than the aforementioned sizes may be appropriately used.

In this embodiment, as the liquid material to be applied to the substrate S, for example, a liquid composition is used which includes a solvent such as hydrazine and oxidizable metals such as a combination of copper (Cu), indium (In), gallium (Ga), and selenium (Se) or a combination of copper (Cu), zinc (Zn), tin (Sn) and selenium (Se). The liquid composition includes a metal material for forming a light absorbing layer (photoelectric conversion layer) of a CIGS solar cell or a CZTS solar cell. Since hydrazine has a relative density higher than that of air, when hydrazine is vaporized and present in the atmosphere, it has a property of tending to move downwardly in a vertical direction.

In this embodiment, as another liquid material, a liquid composition including sodium (Na) dispersed in a solvent such as hydrazine is used. The liquid composition contains a substance for obtaining the grain size of a light absorbing layer of a CIGS solar cell or a CZTS solar cell. Needless to say, as the liquid material, a liquid material in which another oxidizable metal is dispersed in the solution may be used.

(Substrate Loading/Unloading Part)

The substrate loading/unloading part LU loads a substrate S prior to being treated on the coating part CT, and unloads the treated substrate S from the coating part CT. The substrate loading/unloading part LU has a chamber 10. The chamber 10 is formed in the shape of a rectangular box. Inside the chamber 10, an accommodation room 10a capable of accommodating the substrate S is formed. The chamber 10 has a first opening 11, a second opening 12 and a lid portion 14. The first opening 11 and the second opening 12 communicates the accommodation room 10a with the outside of the chamber 10.

The first opening 11 is formed on a +Z-side face of the chamber 10. The first opening 11 is formed to have a size larger than the size of the substrate S as viewed in the Z direction. The substrate S to be taken out of the chamber 10 or the substrate S to be accommodated in the accommodation room 10a is place into or taken out of the substrate loading/unloading part LU through the first opening 11.

The second opening 12 is formed on a +X-side face of the chamber 10. The second opening 12 is formed to have a size larger than the size of the substrate S as viewed in the X direction. The substrate S supplied to the coating part CT or the substrate S returned from the coating part CT is place into or taken out of the substrate loading/unloading part LU through the second opening 12.

The lid portion 14 opens or closes the first opening 11. The lid portion 14 is formed in the shape of a rectangular plate. The lid portion 14 is attached to a +X-side edge of the first opening 11 via a hinge portion (not shown). Thus, the lid portion 14 is rotatable around the Y-axis, with the +X-side edge of the first opening 11 as the center. By rotating the lid portion 14 around the Y-axis, the first opening 11 can be opened or closed.

The accommodation room 10a is provided with a substrate transporting part 15. The substrate transporting part 15 includes a plurality of rollers 17. The rollers 17 are arranged in a pair in the Y-direction, and a plurality of the pairs are arranged in the X-direction.

Each of the rollers 17 is adapted to be rotatable about the Y direction serving as the central axis. The plurality of rollers 17 are formed to have the same diameter, and the +Z-side end of the plurality of rollers 17 are arranged on a same plane parallel to the XY plane. Thus, the plurality of rollers 17 are capable of supporting the substrate S in a state where the substrate S is parallel to the XY plane.

The rotation of each of the rollers 17 is controlled, for example, by a roller-rotation control part (not shown). By rotating each of the rollers 17 clockwise or anti-clockwise around the Y-axis in a state where the substrate S is supported by the plurality of rollers 17, the substrate transporting part 15 can transport the substrate S in an X-direction (+X-direction or −X-direction). As the substrate transporting part 15, a float transporting part (not shown) may be used to lift the substrate for transportation.

(Coating Part)

The coating part CT performs the coating treatment of the liquid material on the substrate S. The coating part CT includes a chamber 20 and a base BC. The coating part CT has a configuration in which the chamber 20 is mounted on the base BC placed on the floor FL.

The chamber 20 is formed in the shape of a rectangular box. Inside the chamber 20, a treatment room 20a is formed. The chamber 20 has a first opening 21 and a second opening 22. The first opening 21 and the second opening 22 communicates the treatment room 20a with the outside of the chamber 20.

The first opening 21 is formed on a −X-side face of the chamber 20. The second opening 22 is formed on a +X-side face of the chamber 20. The first opening 21 and the second opening 22 are formed to have a size which allows the substrate S to pass through. The substrate S is placed into or taken out of the chamber 20 through the first opening 21 and the second opening 22.

The treatment room 20a is provided with an ejection part 31, a maintenance part 32, a liquid material supply part 33, a washing liquid supply part 34, a waste liquid collection part 35, a gas supply/exhaust part 37 and a substrate transporting part 25.

The ejection part 31 has a nozzle NZ, a treatment stage 28 and a nozzle actuator NA.

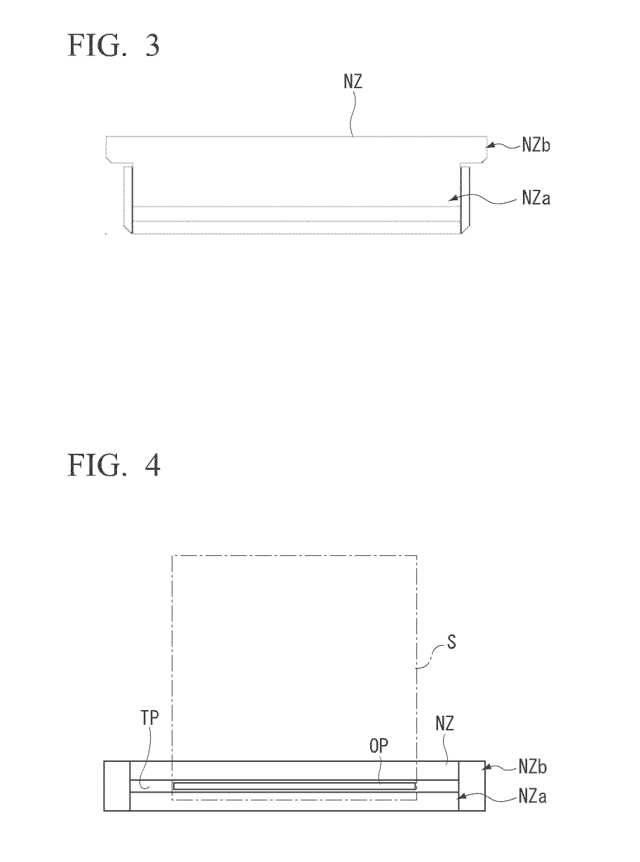

FIG. 3 is a diagram showing a configuration of the nozzle NZ.

As shown in FIG. 3, the nozzle NZ is formed to have an elongate shape, and is arranged such that the lengthwise direction thereof is in parallel to the X direction. The nozzle NZ has a main part NZa and a protruding part NZb. The main part NZa is a housing capable of accommodating the liquid material inside thereof. The main part NZa is made of, for example, a material containing titanium or a titanium alloy. The protruding part NZb is formed to protrude from the main part NZa on the +X-side and the −X-side. The protruding part NZb is held by part of the nozzle actuator NA.

FIG. 4 shows the configuration when the nozzle NZ is viewed from the −Z direction side thereof.

As shown in FIG. 4, the nozzle NZ has an ejection opening OP on the −Z-side end (tip TP) of the main part NZa. The ejection opening OP is an opening for ejecting a liquid material. The ejection opening OP is formed as a slit elonging in the X direction. The ejection opening OP is formed, for example, so that the longitudinal direction thereof is substantially equal to the X-direction dimension of the substrate S.

The nozzle NZ ejects, for example, a liquid material in which four types of metals, namely, Cu, In, Ga, and Se are mixed with a predetermined composition ratio. The nozzle NZ is connected to a liquid supply part 33 via a connection pipe or the like (not shown). The nozzle NZ includes a holding part which holds the liquid material therein. A temperature control part which controls the temperature of the liquid material held by the holding part may be provided.

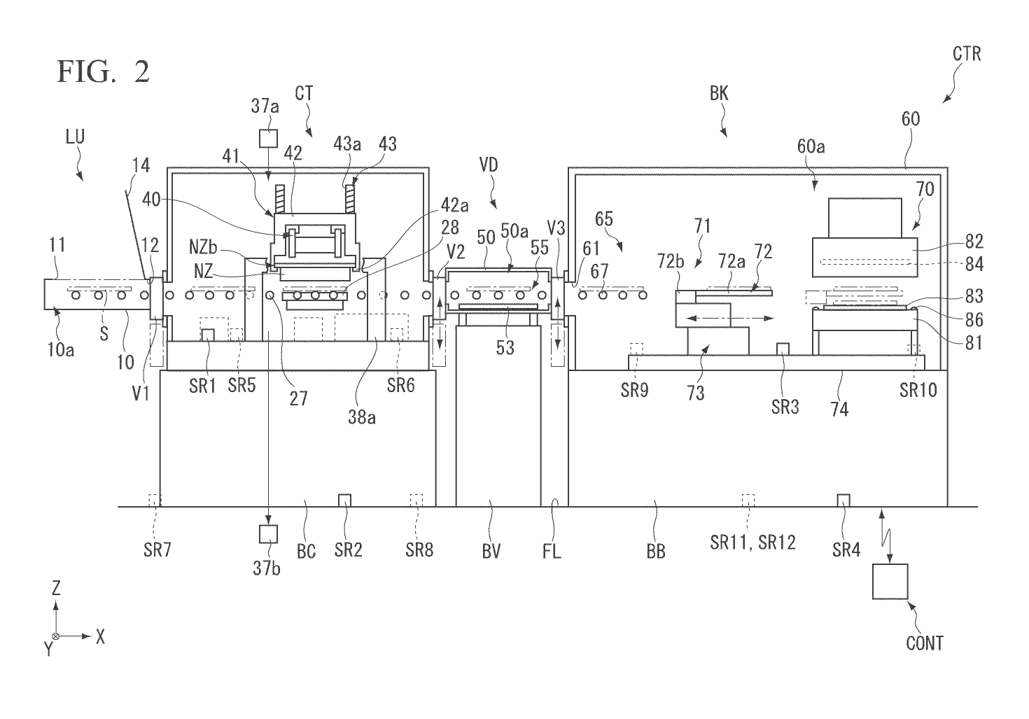

Returning to FIG. 1 and FIG. 2, the substrate S to be subjected to a coating treatment is mounted on the treatment stage 28. The +Z-side face of the treatment stage 28 is a substrate mounting face where the substrate S is mounted. The substrate mounting face is formed to be in parallel with the XY plane. The treatment stage 28 is made of, for example, stainless steel.

The nozzle actuator NA moves the nozzle NZ in the X direction. The nozzle actuator NA has a stator 40 and a mover 41 which constitutes a linear motor mechanism. The stator 40 is elongated in the Y direction. The stator 40 is supported by a support frame 38. The support frame 38 has a first frame 38a and a second frame 38b. The first frame 38a is provided on a −Y-side end portion of the treatment room 20a. The second frame 38b is provided in the treatment room 20a such that the treatment stage 28 is positioned between the first frame 38a and the second frame 38b.

The mover 41 is movable along the direction where the stator 40 is elonged (Y direction). The mover 41 has a nozzle supporting member 42 and an elevator part 43. The nozzle supporting member 42 is formed in the shape of a gate, and has a holding part 42a which holds the protruding part NZb of the nozzle NZ. The nozzle supporting member 42 integrally moves with the elevator part 43 along the stator 40 between the first frame 38a and the second 38b in the Y direction. Thus, the nozzle NZ held by the nozzle supporting member 42 moves in the Y direction over the treatment stage 28. The nozzle supporting member 42 moves along the elevation guide 43a of the elevator part 43 in the Z direction. The mover 41 has an actuator source (not shown) which moves the nozzle supporting member 42 in the Y direction and the Z direction.

The maintenance part 32 has a preliminary ejection part 44, a nozzle-tip washing part 45 and a nozzle standby part 46. The maintenance part 32 is where the maintenance of the nozzle NZ is performed.

The preliminary ejection part 44 receives the liquid material preliminarily ejected from the ejection opening OP of the nozzle NZ. The preliminary ejection part 44 has a first preliminary ejection part 44a and a second preliminary ejection part 44b. The first preliminary ejection part 44a and the second preliminary ejection part 44b are arranged along the moving path of the nozzle NZ in the Y direction, and are provided at a position facing the ejection opening OP.

For example, different types of liquid materials can be ejected to the first preliminary ejection part 44a and the second preliminary ejection part 44b. The first preliminary ejection part 44a and the second preliminary ejection part 44b are formed, for example, in the form of trays, so as to be able to receive the liquid material ejected from the ejection opening OP. In the present embodiment, explanation was given taking example of a configuration including the first preliminary ejection part 44a and the second preliminary ejection part 44b. However, a configuration in which only one preliminary ejection part is provided can be employed. Alternatively, a configuration in which three or more preliminary ejection parts are provided can also be employed.

The nozzle-tip washing part 45 washes the tip TP of the nozzle NZ and the vicinity thereof. The nozzle-tip washing part 45 has a wiping part 45a and a guide rail 45b.

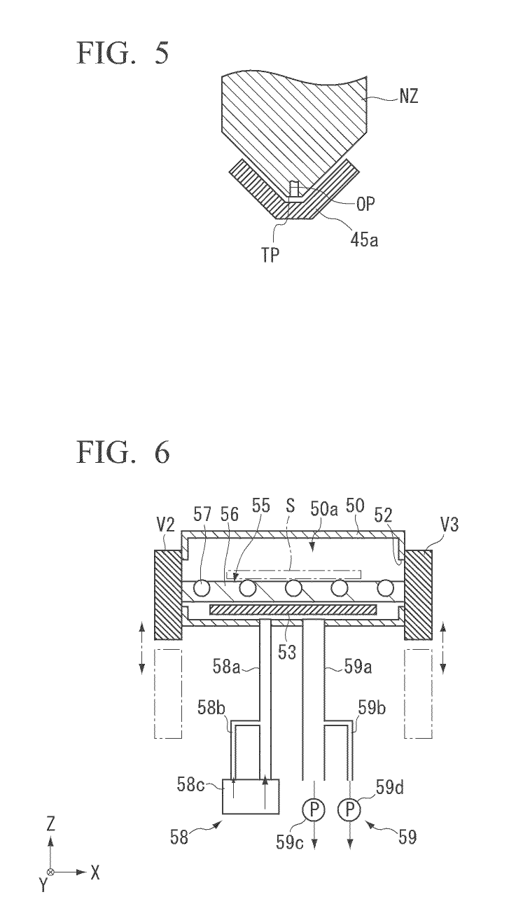

FIG. 5 is a diagram showing the cross-sectional shape of the nozzle NZ and the nozzle-tip washing part 45. As shown in FIG. 5, the wiping part 45a is formed to cover the tip TP of the nozzle NZ and part of the inclined plane on the tip TP-side in the cross-sectional view.

The guide rail 45b extends in the X direction to cover the opening OP of the nozzle NZ. The wiping part 45a is adapted to be movable by an actuator source (not shown) along the guide rail 45b in the X direction. By moving the wiping part 45a in the X direction while being in contact with the tip TP of the nozzle NZ, the tip TP can be wiped.

As shown in FIG. 1, the nozzle standby part 46 is provided between the first frame 38a and the preliminary ejection part 44. In FIG. 1, a state where the nozzle NZ is disposed at the nozzle standby part 46 is shown. The nozzle standby part 46 performs maintenance of the nozzle NZ in a standby state.

The liquid material supply part 33 has a first liquid material accommodation part 33a and a second liquid material accommodation part 33b. The first liquid material accommodation part 33a and the second liquid material accommodation part 33b accommodate the liquid material to be applied to the substrate S. Further, the first liquid material accommodation part 33a and the second liquid material accommodation part 33b are capable of accommodating a plurality of different types of liquid materials.

The washing liquid supply part 34 accommodates a washing liquid which washes the inside of the nozzle NZ. The washing liquid supply part 34 is connected to the inside of the nozzle NZ via a pipe and a pump (which are not shown). The waste liquid storing part 35 collects the liquid ejected from the nozzle NZ. The waste liquid storing part 35 is connected to the first preliminary ejection part 44a and the second preliminary ejection part 44b of the preliminary ejection part 44 via pipes and pumps (which are not shown). Further, a configuration in which the waste liquid storing part 35 is connected to the inside of the nozzle NZ may be employed.

The gas supply/exhaust part 37 has a gas supply part 37a and a gas exhaust part 37b. The gas supply part 37a supplies an inert gas such as a nitrogen gas or an argon gas to the treatment room 20a. The gas exhaust part 37b suctions the treatment room 20a, and discharges the gas in the treatment room 20a outside the chamber 20.

The substrate transporting part 25 transports the substrate S inside the treatment room 20a. The substrate transporting part 25 includes a plurality of rollers 27. The rollers 27 are arranged in the X-direction to be intersected into two lines by a central portion of the treatment room 20a in the Y-direction. The rollers 27 arranged in each line support the +Y-side end and −Y-side end of the substrate S.

By rotating each of the rollers 27 clockwise or anti-clockwise around the Y-axis in a state where the substrate S is supported by the plurality of rollers 27, the substrate S supported by each of the rollers 27 is transported in an X-direction (+X-direction or −X-direction). A float transporting part (not shown) may be used to lift the substrate for transportation.

Further, in the present embodiment, solvent concentration sensors SR1 and SR2 and a removal part 100 are provided. The solvent concentration sensor SR1 detects the concentration of the solvent (in the present embodiment, hydrazine) for the liquid material in the ambient atmosphere, and sends the detection results to the control part CONT. As one example, the solvent concentration sensors R1 and R2 have a suction pump which suctions the gas in the atmosphere, a dry reagent tape which captures the solvent component within the suctioned gas, and a detection part which optically detects the change in the color of the dry reagent tape. By being exposed to hydrazine, the color of the dry reagent tape changes in proportion to the concentration of hydrazine. A configuration is employed in which the detection part optically reads the change in the color, and determines the concentration of hydrazine based on the change in the amount of light.

The solvent concentration sensor SR1 is disposed on the bottom portion (on the −Z-side face) of the treatment room 20a within the chamber 20. The solvent concentration sensor SR2 is provided outside the chamber 20. In the present embodiment, for detecting the concentration of hydrazine which has a larger specific gravity than air, the solvent concentration sensors SR1 and SR2 are disposed on the lower side of the nozzle NZ, the first preliminary ejection part 44a and the second preliminary ejection part 44b in the vertical direction. Further, by providing a solvent concentration sensor SR2 outside the chamber 20, it becomes possible to detect leakage of hydrazine from the chamber 20. The removal part 100 removes the liquid material to be coated on the substrate S from the atmosphere of the treatment room 20a. The removal part 100 has a connection part 101, a recovery part 102 and a recycling part 103.

The connection part 101 includes pipes which connect the first preliminary ejection part 44a and the second preliminary ejection part 44b with the recovery part 102. The connection part 101 is provided with, for example, a pumping mechanism (not shown) (e.g., a suction pump) and a valve (not shown). By opening the valve to actuate the pumping mechanism, suction can be conducted on the bottom of the first preliminary ejection part 44a and the second preliminary ejection part 44b.

The recovery part 102 is connected to the first preliminary ejection part 44a and the second preliminary ejection part 44b via the connection part 101. Substances suctioned from the bottoms of the first preliminary ejection part 44a and the second preliminary ejection part 44b are supplied to the recovery part 102 via the connection part 101. The recovery part 102 has, for example, a liquid material accommodation part such as a bottle or a tank which can accommodate the liquid material to be isolated from the outside. The recovery part 102 is not limited to the aforementioned bottle or tank, and any kind of container formed to be capable of isolating the liquid material can be used. By such a liquid material storing part, the liquid material discharged from the connection part 101 can be temporarily stored. The recovered liquid material (the liquid material inside the liquid material storing part) is supplied to the recycling part 103.

The recycling part 103 is a pipe in which one end thereof is connected to the recovery part 102, and the other end thereof is connected to the nozzle NZ. The recycling part 103 allows the liquid material recovered by the recovery part 102 to flow to the nozzle NZ. The recycling part 103 is provided with, for example, a pump (not shown) (e.g., a suction pump) and a valve (not shown) within the flow path thereof. By opening the valve to actuate the pump, the liquid material can be supplied from the recovery part 102 to the nozzle NZ via the recycling part 103.

Further, the recovery part 102 may be provided with an absorptiometer or a viscometer (not shown), so as to determine the deterioration state of the liquid material. In an embodiment where the deterioration state of the liquid material is determined using an absorptiometer or a viscometer, for example, the liquid material which has exceeded the first threshold value can be reprepared to be reproduced and supplied to the nozzle NZ via the recycling part 103, and the liquid material which has exceeded the second threshold value can be discarded.

(Vacuum Drying Part)

The vacuum drying part VD dries the liquid material coated on the substrate S. The vacuum drying part VD has a chamber 50, a base BV and gate valves V2 and V3. The vacuum drying part VD has a configuration in which the chamber 50 is mounted on the base BV placed on the floor FL.

The chamber 50 is formed in the shape of a rectangular box. Inside the chamber 50, a treatment room 50a is formed. The chamber 50 has a first opening 51 and a second opening 52. The first opening 51 and the second opening 52 communicates the treatment room 50a with the outside of the chamber 50.

The first opening 51 is formed on a −X-side face of the chamber 50. The second opening 52 is formed on a +X-side face of the chamber 50. The first opening 51 and the second opening 52 are formed to have a size which allows the substrate S to pass through. The substrate S is placed into or taken out of the chamber 50 through the first opening 51 and the second opening 52.

The treatment room 50a is provided with a substrate transporting part 55, a gas supply part 58, a gas exhaust part 59 and a heating part 53 (see FIG. 6).

The substrate transporting part 55 includes a plurality of rollers 57. The rollers 57 are arranged in a pair in the Y-direction, and a plurality of the pairs are arranged in the X-direction. The plurality of rollers 57 supports the substrate S which is disposed in the treatment room 50a via the first opening 51.

By rotating each of the rollers 57 clockwise or anti-clockwise around the Y-axis in a state where the substrate S is supported by the plurality of rollers 57, the substrate S supported by each of the rollers 57 is transported in an X-direction (+X-direction or −X-direction). A float transporting part (not shown) may be used to lift the substrate for transportation.

FIG. 6 is a schematic diagram showing a configuration of the vacuum drying part VD.

As shown in FIG. 6, the gas supply part 58 supplies an inert gas such as a nitrogen gas or an argon gas to the treatment room 50a. The gas supply part 58 has a first supply part 58a and a second supply part 58b. The first supply part 58a and the second supply part 58b are connected to a gas supply source 58c such as a gas bomb or a gas pipe. Supplying of a gas to the treatment room 50a is performed mainly by using the first supply part 58a. The second supply part 58b makes a fine control of the amount of gas supplied by the first supply part 58a.

The gas exhaust part 59 suctions the treatment room 50a, and discharges the gas in the treatment room 50a outside the chamber 50, thereby reducing the pressure inside the treatment room 50a. By reducing the pressure inside the treatment room 50a, evaporation of the solvent contained in the liquid material on the substrate S can be promoted, thereby drying the liquid material. The gas exhaust part 59 has a first suction part 59a and a second suction part 59b. The first suction part 59a and the second suction part 59b are connected to a suction source 59c and 59d such as a pump. Suction from the treatment room 50a is performed mainly by using the first suction part 59a. The second suction part 59b makes a fine control of the amount of suction by the first suction part 59a.

The heating part 53 heats the liquid material on the substrate S disposed in the treatment room 50a. As the heating part 53, an infrared device or a hot plate is used. The temperature of the heating part 53 can be controlled, for example, from room temperature to about 100° C. By using the heating part 53, evaporation of the solvent contained in the liquid material on the substrate S can be promoted, thereby supporting the drying treatment under reduced pressure.

(Baking Part)

The baking part BK bakes the coating film coated on the substrate S. The baking part BK includes a chamber 60 and a base BB. The baking part BK has a configuration in which the chamber 60 is mounted on the base BB placed on the floor FL.

The chamber 60 is formed in the shape of a rectangular box. Inside the chamber 60, a treatment room 60a is formed. The chamber 60 has an opening 61. The opening 61 communicates the treatment room 60a with the outside of the chamber 60. The opening 61 is formed on a −X-side face of the chamber 60. The opening 61 is formed to have a size which allows the substrate S to pass through. The substrate S is placed into or taken out of the chamber 60 through the opening 61.

The treatment room 60a is provided with a substrate transporting part 65 and a heating part 70.

The substrate transporting part 65 has a plurality of rollers 67 and an arm part 71. The rollers 67 are arranged in a pair in the Y-direction, and a plurality of the pairs are arranged in the X-direction. The plurality of rollers 67 supports the substrate S which is disposed in the treatment room 60a via the opening 61.

By rotating each of the rollers 67 clockwise or anti-clockwise around the Y-axis in a state where the substrate S is supported by the plurality of rollers 67, the substrate S supported by each of the rollers 67 is transported in an X-direction (+X-direction or −X-direction). A float transporting part (not shown) may be used to lift the substrate for transportation.

The arm part 71 is disposed on a platform 74, and transfers the substrate S between the plurality of rollers 67 and the heating part 70. The arm part 71 has a transport arm 72 and an arm actuator 73. The transport arm 72 has a substrate supporting part 72a and a moving part 72b. The substrate supporting part 72a supports the +Y-side edge and −Y-side edge of the substrate S. The moving part 72b is attached to the substrate supporting part 72a, and is movable in the X-direction and the θZ-direction.

The arm actuator 73 actuates the moving part 72b in the X-direction or the θZ-direction. When the moving part 72b is moved in the +X-direction by the arm actuator 73, the substrate supporting part 72a is inserted inside the heating part 70, and the substrate S is placed at a central portion of the heating part 70 as viewed in the Z-direction.

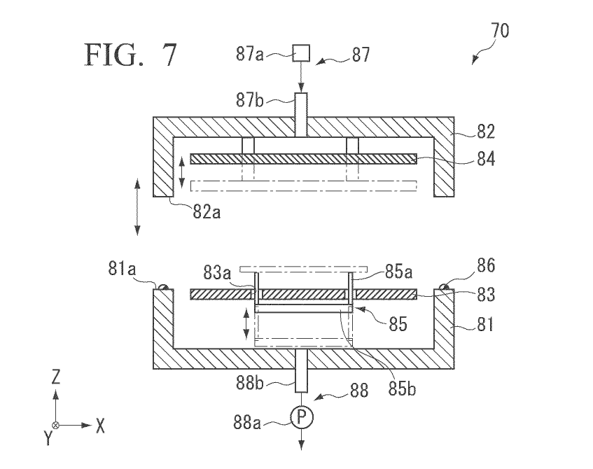

FIG. 7 is a cross-sectional view showing the configuration of the heating part 70. As shown in FIG. 7, the heating part 70 is disposed on the platform 74, and has a first accommodation part 81, a second accommodation part 82, a first heating plate 83, a second heating plate 84, a lifting part 85, a sealing part 86, a gas supply part 87 and an exhaust part 88.

The first accommodation part 81 is formed in the shape of a rectangular open box as viewed in the Z-direction, and is mounted on the bottom of the chamber 60 such that the opening faces the +Z side. The second accommodation part 82 is formed in the shape of a rectangular open box as viewed in the Z-direction, and is disposed such that the opening faces the first accommodation part 81. The second accommodation part 82 is movable in the Z direction by using a lifting mechanism (not shown). By superimposing the edge portion 82a of the second accommodation part 82 on the edge 81a of the first accommodation part 81, the inside of the first accommodation part 81 and the second accommodation part 82 is closed.

The first heating plate 83 is accommodated in the first accommodation part 81. The first heating part 83 heats a substrate S in a state where the substrate S is mounted on the first heating part 83. The first heating plate 83 is formed of, for example, quartz or the like, and is provided with a heating device such as an infrared device or a hot plate inside thereof. The temperature of the first heating plate 83 is adjustable, for example, from about 200 to 800° C. The first heating part 83 has a plurality of through-holes 83a formed thereon. The through-holes 83a allow part of the lifting part 85 to penetrate therethrough.

The second heating plate 84 is accommodated in the second accommodation part 82. The second heating plate 84 is formed of, for example, a metal material, and is provided with a heating device such as an infrared device or a hot plate inside thereof. The temperature of the second heating plate 84 is adjustable, for example, from about 200 to 800° C. The second heating plate 84 is provided to be movable independently from the second accommodation part 82 in the Z direction by a lifting mechanism (not shown). By moving the second heating plate 84 in the Z direction, the interval between the second heating plate 84 and the substrate S can be adjusted.

The lifting part 85 moves the substrate S between the arm part 71 and the first heating plate 83. The lifting part 85 has a plurality of support pins 85a and a moving part 85b which is movable in the Z direction while holding the support pins 85a. For easier discrimination of the drawings, in FIG. 7, a configuration is shown in which two support pins 85a are provided. However, in practice, it is possible to provide, for example, sixteen support pins 85a (see FIG. 7). The plurality of through-holes 83a provided on the first heating plate 83 are arranged at positions corresponding to the plurality of support pins 85a as viewed in the Z direction.

The sealing part 86 is formed on the edge portion 81a of the first accommodation part 81. As the sealing part 86, for example, an O-ring formed by a resin material or the like can be used. The sealing part 86 seals the first accommodation part 81 and the second accommodation part 82 in a state where the edge portion 82a of the second accommodation part 82 is superimposed on the first edge 81a of the first accommodation part 81. In this manner, the inside of the first accommodation part 81 and the second accommodation part 82 can be closed.

The gas supply part 87 supplies a nitrogen gas or the like to the treatment room 60a. The gas supply part 87 is connected to the +Z-side face of the chamber 60. The gas supply part 87 has a gas supply source 87a such as a gas bomb or a gas pipe, and a connection pipe 87b which connects the gas supply source 87a with the chamber 60.

The exhaust part 88 suctions the treatment room 60a, and discharges the gas in the treatment room 80a outside the chamber 60. The exhaust part 88 is connected to the −Z-side face of the chamber 60. The exhaust part 88 has a suction source 88a such as a pump, and a connection pipe 88b which connects the suction source 88a with the chamber 60.

Further, in the present embodiment, solvent concentration sensors SR3 and SR4 are provided. Like the aforementioned solvent concentration sensors SR1 and SR2, the solvent concentration sensors SR3 and SR4 detects the concentration of the solvent (in the present embodiment, hydrazine) for the liquid material in the ambient atmosphere, and sends the detection results to the control part CONT. The solvent concentration sensor SR3 is provided on the platform 74 on the +Y side of the heating part 70 within the treatment room 60a. The solvent concentration sensor SR3 is provided at a position remote from the heating part 70. The solvent concentration sensor SR4 is provided outside the chamber 60. In the present embodiment, for detecting the concentration of hydrazine which has a larger specific gravity than air, like the solvent concentration sensors SR1 and SR2, the solvent concentration sensors SR3 and SR4 are disposed on the lower side of the transport path of the substrate S in the vertical direction. Further, by providing a solvent concentration sensor SR4 outside the chamber 60, it becomes possible to detect leakage of hydrazine from the chamber 60.

(Substrate Transport Path)

The second opening 12 of the substrate loading/unloading part LU, the first opening 21 and the second opening 22 of the coating part CT, the first opening 51 and the second opening 52 of the vacuum drying part VD and the opening 61 of the baking part BK are provided along a line in parallel to the X-direction. Thus, the substrate S is moved along a line in the X-direction. Further, in the path from the substrate loading/unloading part LU to the heating part 70 of the baking part BK, the position in the Z-direction is maintained. Thus, stirring of the gas around the substrate S can be suppressed.

(Anti-Chamber)

As shown in FIG. 1, the chamber 20 has anti-chambers AL1 to AL3 connected thereto.

The anti-chambers AL1 to AL3 are provided to communicate with the inside and outside of the chamber 20. Each of the anti-chambers AL1 to AL3 is a path through which a component of the treatment room 20a is taken out of the chamber 20 or the component is placed into the treatment room 20a from outside the chamber 20.

The anti-chamber AL1 is connected to the ejection part 31. The nozzle NZ provided in the ejection part 31 can be taken out of or placed into the treatment room 20a via the anti-chamber AL1. The anti-chamber AL2 is connected to the liquid material supply part 33. The liquid material supply part 33 can be taken out of or placed into the treatment room 20a via the anti-chamber AL2.

The anti-chamber AL3 is connected to a liquid material preparation part (not shown). In the liquid material preparation part, a liquid can be taken out of or placed into the treatment room 20a via the anti-chamber AL3. The anti-chamber AL3 is formed to have a size which allows the substrate S to pass through. Therefore, for example, when a test coating of the liquid material is to be conducted in the coating part CT, a substrate S prior to treatment can be supplied to the treatment room 20a from the anti-chamber AL3. Further, the substrate S after the test coating can be taken out from the anti-chamber AL3. Moreover, the substrate S can be taken out from the anti-chamber AL3 temporarily in emergency.

The chamber 60 has an anti-chamber AL4 connected thereto.

The anti-chamber AL4 is connected to the heating part 70. The anti-chamber AL4 is formed to have a size which allows the substrate S to pass through. Therefore, for example, when heating of the substrate S is to be conducted in the heating part 70, the substrate S can be supplied to the treatment room 60a from the anti-chamber AL4. Further, the substrate S after the heat treatment can be taken out from the anti-chamber AL4.

(Glove Part)

As shown in FIG. 1, the chamber 20 has a glove part GX1 connected thereto. Further, the chamber 60 has a glove part GX2 connected thereto.

The glove parts GX1 and GX2 are parts where an operator accesses the inside of the chamber 20 and the chamber 60. By inserting the hands inside the glove parts GX1 and GX2, the operator can conduct maintenance inside the chamber 20 and the chamber 60. The glove parts GX1 and GX2 are formed to have a bag-like shape. The glove parts GX1 and GX2 are respectively provided at a plurality of portions on the chamber 20 and the chamber 60. A sensor may be provided inside the chamber 20 and the chamber 60 which detects whether or not an operator has put his hand in the glove part GX1 or GX2.

(Gate Valve)

Between the second opening 12 of the substrate loading/unloading part LU and the first opening 21 of the coating part CT, a gate valve V1 is provided. The gate valve V1 is provided to be movable in the Z-direction by an actuator (not shown). By moving the gate valve V1 in the Z-direction, the second opening 12 of the substrate loading/unloading part LU and the first opening 21 of the coating part CT are simultaneously opened or closed. When the second opening 12 and the first opening 21 are simultaneously opened, a substrate S can be moved through the second opening 12 and the first opening 21.

Between the second opening 22 of the coating part CT and the first opening 51 of the vacuum drying part VD, a gate valve V2 is provided. The gate valve V2 is provided to be movable in the Z-direction by an actuator (not shown). By moving the gate valve V2 in the Z-direction, the second opening 22 of the coating part CT and the first opening 51 of the vacuum drying part VD are simultaneously opened or closed. When the second opening 22 and the first opening 51 are simultaneously opened, a substrate S can be moved through the second opening 22 and the first opening 51.

Between the second opening 52 of the vacuum drying part VD and the opening 61 of the baking part BK, a gate valve V3 is provided. The gate valve V3 is provided to be movable in the Z-direction by an actuator (not shown). By moving the gate valve V3 in the Z-direction, the second opening 52 of the vacuum drying part VD and the opening 61 of the baking part BK are simultaneously opened or closed. When the second opening 52 and the opening 61 are simultaneously opened, a substrate S can be moved through the second opening 52 and the opening 61.

(Control Device)

The control part CONT is a part which has the overall control of the coating apparatus CTR. Specifically, the control part CONT controls the operations of the substrate loading/unloading part LU, the coating part CT, the vacuum drying part VD, the baking part BK, the removal part 100 and the gate valves V1 to V3. As an example of the controlling operation, the control part CONT controls the amount of gas to be supplied from the gas supply part 37a, based on the detection results of the solvent concentration sensors SR1 to SR4, and allows the recovery part 102 to conduct a recovery operation. The control part CONT has a timer or the like (not shown) for measuring the treatment time.

(Coating Method)

Next, a coating method according to one embodiment of the present invention will be described. In this embodiment, a coating film is formed on the substrate S by using the coating apparatus CTR having the above-described configuration. The operations performed by the respective parts of the coating apparatus CTR are controlled by the control part CONT.

Firstly, the control part CONT loads a substrate S on the substrate loading/unloading part LU from the outside. In this case, the control part CONT closes the gate valve V1, opens the lid portion 14 and accommodates the substrate S in the accommodation room 10a of the chamber 10. After the substrate S is accommodated in the accommodation room 10a, the control part CONT closes the lid portion 14.

After the lid portion 14 is closed, the control part CONT opens the gate valve V1, so as to communicate the accommodation room 10a of the chamber 10 with the treatment room 20a of the chamber 20 of the coating part CT. After opening the gate valve V1, the control part CONT transports the substrate S in the X-direction using the substrate transporting part 15.

After a portion of the substrate S has been inserted into the treatment room 20a of the coating part CT, the control part CONT uses the substrate transporting part 25 to completely load the substrate S into the treatment room 20a. After the substrate S has been loaded, the control part CONT closes the gate valve V1. After closing the gate valve V1, the control part CONT transports the substrate S to the treatment stage 28.

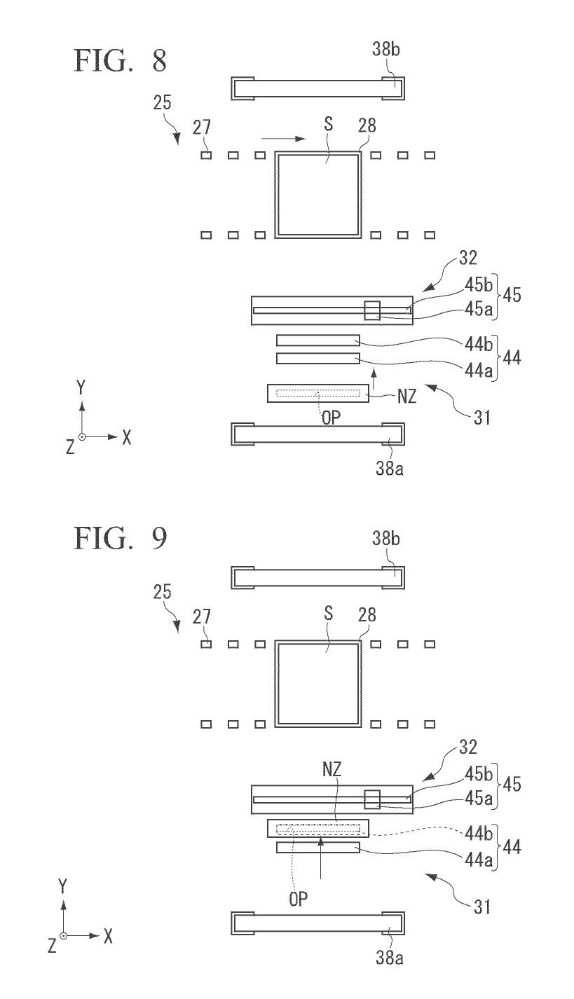

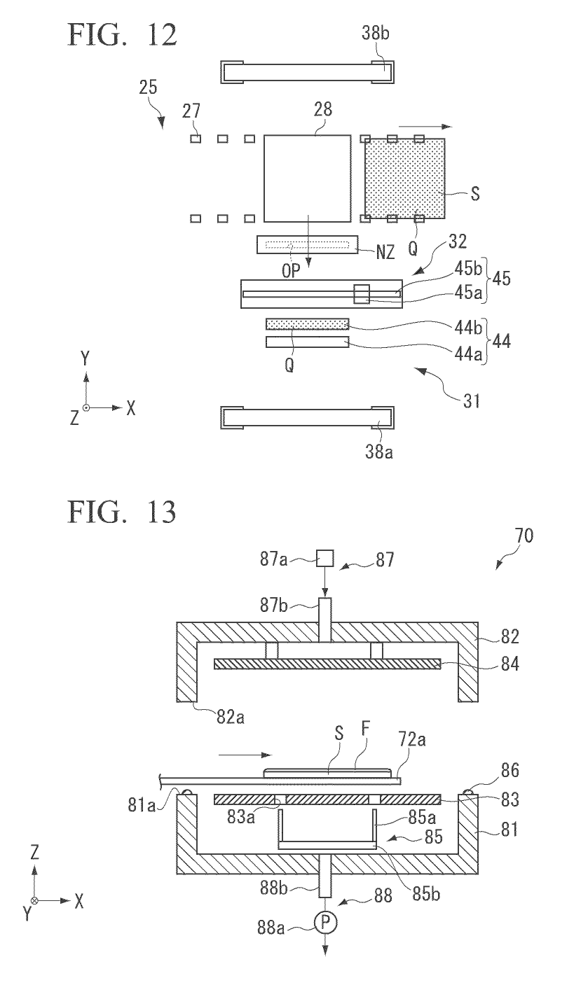

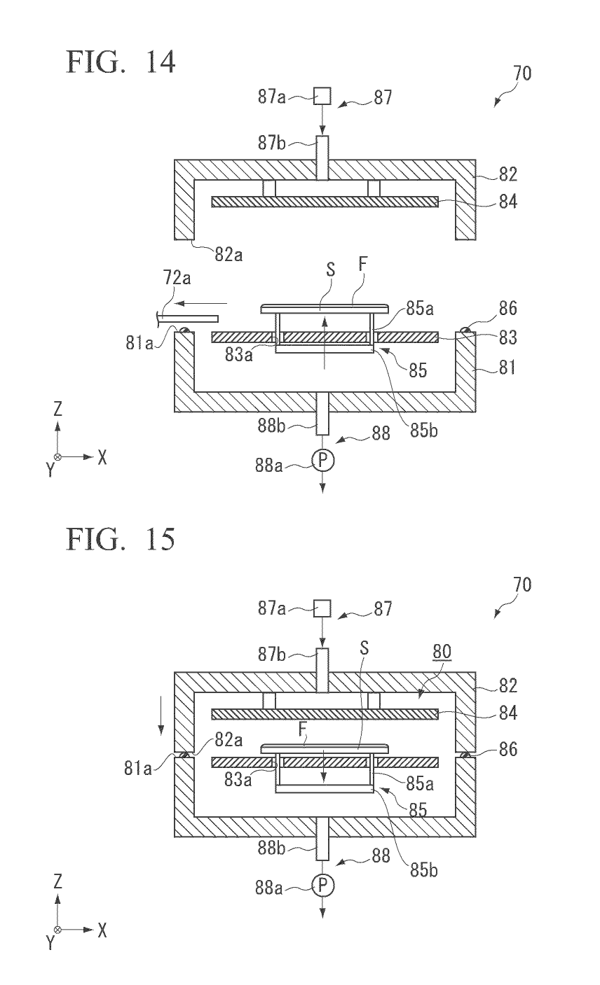

FIG. 8 is a diagram showing a simplified configuration of the coating part CT in which part of the components have been abbreviated. Herebelow, the same applies to FIG. 9 to FIG. 12. As shown in FIG. 8, when the substrate S is mounted on the treatment stage 28, a coating treatment is conducted by the coating part CT. Prior to the coating treatment, the control part CONT closes the gate valves V1 and V2, and conducts supplying and suctioning of an inert gas using the gas supplying part 37a and the gas exhaust part 37b. By this operation, the atmosphere and the pressure of the treatment room 20a can be adjusted. After adjusting the atmosphere and the pressure of the treatment room 20a, the control part CONT uses the nozzle actuator NA (not shown in FIG. 8) to move the nozzle NZ from the nozzle standby part 46 to the +Y-direction. Thereafter, during the coating treatment, the control part CONT continuously conducts the adjusting operation of the atmosphere and the pressure of the treatment room 20a.

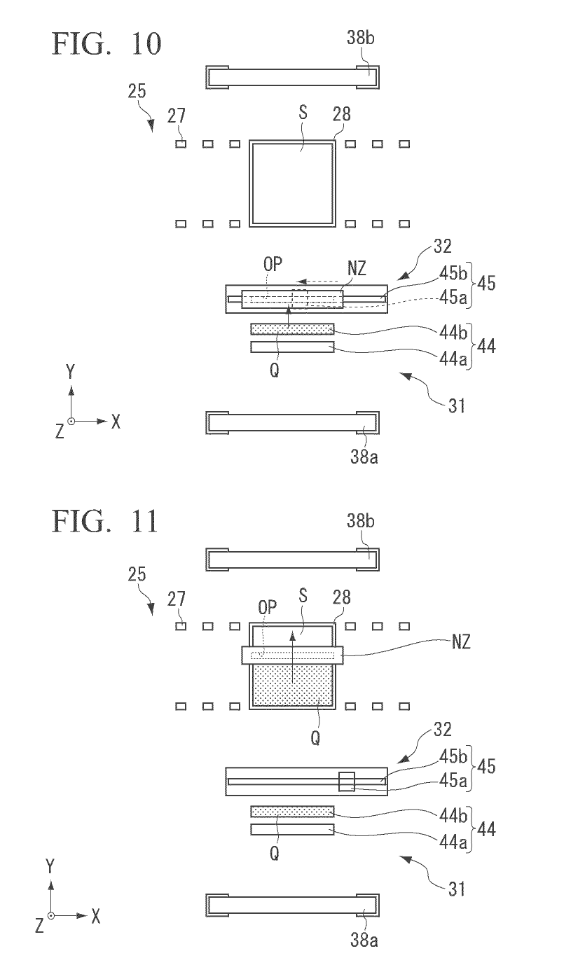

When the nozzle NZ reaches the preliminary ejection part 44, as shown in FIG. 9, the control part CONT conducts a preliminary ejection operation at at least one of the first preliminary ejection part 44a and the second preliminary ejection part 44b. Here, explanation will be given below, taking an example of a case where a preliminary ejection operation is conducted at the second preliminary ejection part 44b. In the preliminary ejection operation, the control part CONT ejects the liquid material Q from the ejection opening OP in a state where the ejection opening OP faces the second preliminary ejection part 44b (see FIG. 10). The ejected liquid material is accommodated in the second preliminary ejection part 44b.

After the preliminary ejection operation, the control part CONT moves the nozzle NZ to the nozzle tip washing part 45. After the nozzle NZ reaches the nozzle tip washing part 45, as shown in FIG. 10, the control part CONT moves the wiping part 45a along the guide rail 45b in the X-direction, so as to wipe the tip TP of the nozzle NZ and the inclined part in the vicinity thereof.

After wiping the tip TP of the nozzle NZ, the control part CONT moves the nozzle NZ to the treatment stage 28. After the ejection opening OP of the nozzle NZ reaches the −Y-side end of the substrate S, as shown in FIG. 11, the control part CONT ejects the liquid material Q from the ejection opening OP to the substrate S while moving the nozzle NZ in the +Y-direction at a predetermined speed. By this operation, a coating film of the liquid material Q is formed on the substrate S.

After forming a coating film of the liquid material Q on a predetermined region of the substrate S, the control part CONT uses the substrate transporting part 25 to move the substrate S from the treatment stage 28 in the +X-direction. Further, the control part CONT moves the nozzle NZ in the −Y-direction, and returns the nozzle NZ to the nozzle standby part 46.

After the substrate S reaches the second opening 22 of the chamber 20, the control part CONT opens the gate valve V2, and transports the substrate S from the coating part CT to the vacuum drying part VD. After the substrate S is accommodated in the treatment room 50a of the chamber 50 provided in the vacuum drying part VD, the control part CONT closes the gate valve V2, and performs a vacuum drying treatment of the substrate S in the treatment room 50a. After the vacuum drying treatment, the control part CONT uses the gas supply part 58 to adjust the atmosphere inside the treatment room 50a and uses the gas exhaust part 59 to reduce the pressure inside the treatment room 50a. When the pressure inside the treatment room 50a is reduced by this operation, evaporation of the solvent contained in the coating film of the liquid material Q formed on the substrate S is promoted, and the coating film is dried. The control part CONT may use the heating part 53, so as to promote evaporation of the solvent contained in the liquid material on the substrate S, thereby supporting the vacuum drying treatment. By this treatment, a coating film F is formed on the substrate S (see FIG. 13).

After the vacuum drying treatment, the control part CONT opens the gate valve V3, and transports the substrate S from the vacuum drying part VD to the baking part BK. After the substrate S is accommodated in the treatment room 60a of the chamber 60 provided in the baking part BK, the control part CONT closes the gate valve V3.

After the substrate S has been disposed at a central portion above the first heating plate 83 by the movement of the substrate supporting part 72a, the control part CONT moves the lifting part 85 in the +Z direction. By this operation, the substrate S leaves the substrate supporting part 72a of the transport arm 72, and is supported by the plurality of support pins 85a of the lifting part 85. In this manner, the substrate S is delivered from the substrate supporting part 72a to the lifting part 85. After the substrate S has been supported by the support pins 85a of the lifting part 85, the control part CONT withdraws the substrate supporting part 72a outside the heating part 70 in the −X direction.

After withdrawing the substrate supporting part 72a, as shown in FIG. 15, the control part CONT moves the lifting part 85 in the −Z direction, and also moves the second accommodation part 82 in the −Z direction. By this operation, the edge portion 82a of the second accommodation part 82 is superimposed on the edge 81a of the first accommodation part 81, so that the sealing part 86 is sandwiched between the edge portion 82a and the edge portion 81a. As a result, a closed baking room 80 is formed by the first accommodation part 81, the second accommodation part 82 and the sealing part 86.

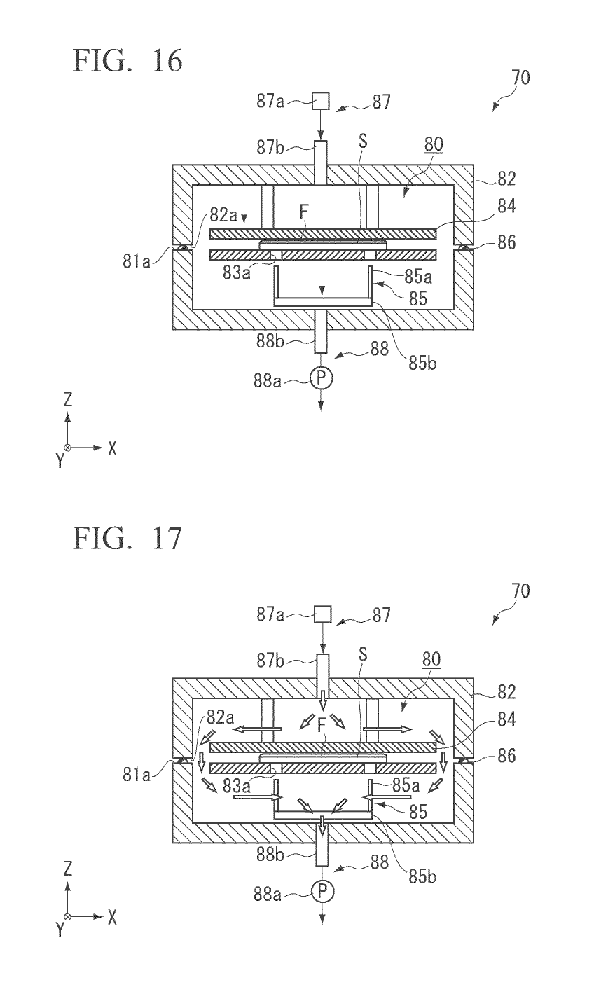

After forming the baking room 80, as shown in FIG. 16, the control part CONT moves the lifting part 85 in the −Z direction and mounts the substrate S on the first heating plate 83. After the substrate S has been mounted on the first heating plate 83, the control part CONT moves the second heating plate 84 in the −Z direction, so that the second heating plate 84 approaches the substrate S. The control part CONT appropriately adjusts the position of the second heating plate 84 in the Z direction.

After adjusting the position of the second heating plate 84 in the Z direction, as shown in FIG. 17, a hydrogen sulfide gas is supplied to the baking room 80 by using the gas supply part 87, and the baking room 80 is suctioned by using the exhaust part 88. By this operation, not only the atmosphere and pressure inside the baking room 80 are adjusted, but also a stream of the hydrogen sulfide gas is formed from the second accommodation part 82 to the first accommodation part 81. In a state where the stream of the hydrogen sulfide gas is formed, the control part CONT actuates the first heating plate 83 and the second heating plate 84, so as to perform the baking operation of the substrate S. By this operation, the solvent component evaporated from the coating film F and the like are swept away by the stream, and suctioned by the exhaust part 88.

After the baking operation has been completed, the control part CONT transports the substrate S in the −X direction. Specifically, the substrate S is unloaded from the baking part BK via the heating part 70, the arm part 71 and the substrate transporting part 65, and is returned to the substrate loading/unloading part LU via the vacuum drying part VD and the coating part CT. After the substrate S has been returned to the substrate loading/unloading part LU, the control part CONT opens the lid portion 14 in a state where the gate valve V1 is closed. Thereafter, an operator collects the substrate S in the chamber 10, and accommodates a new substrate S in the accommodation room 10a of the chamber 10.

In the case where, after the substrate S has been returned to the substrate loading/unloading part LU, another coating film is formed to be superimposed on the coating film F formed on the substrate S, the control part CONT transports the substrate S to the coating part CT again, and repeats the coating treatment, the vacuum drying treatment and the baking treatment. In this manner, a coating film F is formed on the substrate S.

In the sequence of the aforementioned operations, when the concentration of the solvent (hydrazine) becomes high in the atmosphere of the coating environment, there is a possibility that the ambient apparatuses and environment are affected. Thus, in a first mode of the present embodiment, the control part CONT adjusts the hydrazine concentration within the atmosphere inside the chamber 20 by using the gas supply/exhaust part 37. More specifically, the control part CONT supplies an inert gas to the inside of the chamber 20 by using the inert gas supply part 37 (inert gas supplying step).

In the inert gas supplying step, the control part CONT first detects the hydrazine concentration within the atmosphere at various parts of the coating apparatus CTR by using the solvent concentration sensors SR1 to SR4 (detecting step). The control part CONT adjusts the amount of inert gas supplied from the gas supply part 37a on the basis of the detection result obtained in the detecting step, and supplies the inert gas to the inside of the chamber 20. For example, when the detected hydrazine concentration exceeds a predetermined threshold value, it is possible to supply the inert gas into the chamber 20. The threshold value may be obtained in advance by a test or simulation, and may be stored in the control part CONT. In addition, for example, a predetermined amount of the inert gas may be constantly supplied into the chamber 20 during the coating operation, the vacuum drying operation and the baking operation, and the amount of the inert gas to be supplied can be increased or decreased on the basis of the detection result of the solvent concentration sensors SR1 to SR4.

Moreover, when the detection results of the solvent sensor SR2 provided outside the chamber 20 or the solvent sensor SR4 provided outside the chamber 60 exceed a predetermined threshold value, it means that hydrazine is leaking to the outside of the chamber 20 or the chamber 60. Therefore, in such a case, an operation can be conducted to give warning that the ambient environment is changing by the leakage of hydrazine by using a sound or a light. In this manner, for example, it becomes possible to promptly inform the change in the environment to the workers and the like in the vicinity.

In a second mode of the present embodiment, when the hydrazine concentration exceeds a predetermined threshold value within the atmosphere of the coating part CT and the baking part BK of the coating apparatus CTR, the removal part 100 is used to isolate the liquid material inside the chamber 20 from the ambient atmosphere (removing step). In the removing step, a first threshold value and a second threshold value are predetermined. The first threshold value indicates a slight excess in the level of the hydrazine concentration within the atmosphere inside the coating part CT and the baking part BK, and the second threshold value indicates a serious excess in the level of the hydrazine concentration within the aforementioned atmosphere.

The control part CONT first detects the hydrazine concentration within the atmosphere inside the coating part CT and the baking part BK by using the solvent concentration sensors SR1 to SR4. When the hydrazine concentration exceeds the first threshold value (when the hydrazine concentration satisfies the requirement: first threshold value<hydrazine concentration<second threshold value), the control part CONT transports the substrate S outside the chamber 20, so that the substrate S is not disposed inside the chamber 20.

In the case where coating of the substrate S is being conducted by the nozzle NZ when the hydrazine concentration within the aforementioned atmosphere exceeds the first threshold value, the substrate S is transported outside the chamber 20 after the coating of the substrate S is completed. In this case, the outside of the chamber 20 includes, for example, the substrate loading/unloading part LU and the vacuum drying part VD. Alternatively, a mode in which the substrate S is transported outside the coating apparatus CTR via the anti chamber AL3 may be employed. By this operation, the substrate S can be prevented from being transported outside the chamber 20 before the coating operation is completed, thereby preventing a waste of the substrate S. The coating apparatus is controlled such that a new substrate S will not be loaded after transporting the substrate S outside the chamber 20.

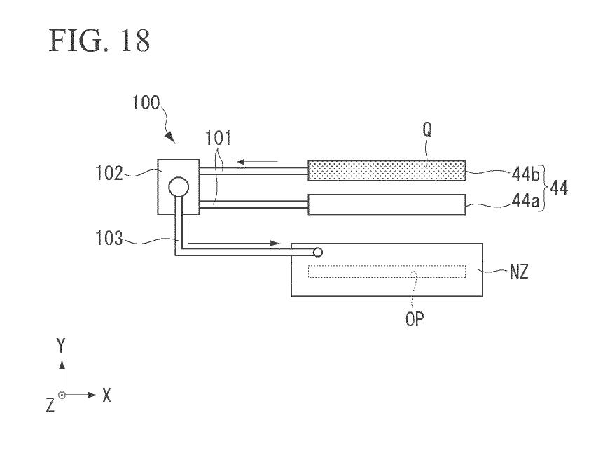

When the substrate S is no longer disposed inside the chamber 20, the control part CONT discharges the liquid material inside the nozzle NZ to the preliminary ejection part 44. In this operation, firstly, the control part CONT moves the nozzle NZ to one of the first preliminary ejection part 44a and the second preliminary ejection part 44b (in the present embodiment, explanation will be given, taking example of the second preliminary ejection part 44b). After moving the nozzle NZ, as shown in FIG. 18, the control part CONT ejects the liquid material Q from the nozzle NZ to the second preliminary ejection part 44b. In this case, for example, the control part CONT closes the supply path of the liquid material so that no more liquid material would be supplied to the nozzle NZ, and an inert gas is supplied to the nozzle NZ to discharge all of the liquid material inside the nozzle NZ.

When the liquid material is ejected from the nozzle NZ, the control part CONT uses the removal part 100 to discharge the liquid material. More specifically, the control part CONT opens the valve (not shown) provided in the connection part 101 to actuate the pumping mechanism (not shown), and discharges the liquid material accommodated in the second preliminary ejection part 44b to the connection part 101. A bubble sensor may be provided at the second preliminary ejection part 44b, and the bubble sensor or a timer in the control part CONT may be used to confirm whether or not all of the liquid material at the second preliminary ejection part 44b has been discharged. By these operations, the liquid material Q inside the chamber 20 is isolated. After all of the liquid material at the second preliminary ejection part 44b has been isolated, the control part CONT stops actuation of the pumping mechanism in the connection part 101, and closes the valve (not shown).

In the removing step, the control part CONT performs an operation to discharge hydrazine within the aforementioned atmosphere in response to the detection results obtained by the solvent concentration sensors SR1 to SR4 which shows that a predetermined threshold value has been exceeded (discharging step). For example, when a detection result is obtained by at least one of the solvent concentration sensors SR1 and SR2 which shows that a predetermined threshold value has been exceeded, hydrazine inside the chamber 20 is discharged. Further, when a detection result is obtained by at least one of the solvent concentration sensors SR3 and SR4 which shows that a predetermined threshold value has been exceeded, hydrazine inside the chamber 60 is discharged. In the discharging step, the control part CONT performs the same operation as in the aforementioned inert gas supplying step to discharge hydrazine inside the chamber 20 and the chamber 60. The control part CONT may perform the discharging step at the same time as the removing step or after the removing step.

In the present embodiment, since the connection part 101 is connected to the recovery part 102, the liquid material isolated in the removing step is recovered by the recovery part 102 (recovering step). For example, when the detection results of the solvent concentration sensors SR1 to SR4 fall below the first threshold value (i.e., when the hydrazine concentration within the atmosphere satisfies the requirement hydrazine concentration<first threshold value), the control part CONT actuates a pumping mechanism (not shown) provided in the recycling part 103 to supply the liquid material within the recovery unit 102 to the recycling part 103. More specifically, the control part CONT performs an operation to recycle the liquid material to the nozzle NZ via the recycling part 103 (recycling step). By this operation, the isolated liquid material is returned to the nozzle NZ, so that there is no need to use a new liquid material. As a result, the amount of the liquid material used can be reduced.

On the other hand, for example, when the hydrazine concentration within the atmosphere inside the chamber 20 exceeds the second threshold value (i.e., when the hydrazine concentration within the atmosphere satisfies the requirement second threshold value<hydrazine concentration), all operations of the coating apparatus CTR are stopped. When the hydrazine concentration within the atmosphere becomes high, it is sometimes preferable to perform an emergency stop of the coating apparatus CTR itself prior to removing the liquid material. In such a case, for example, even when coating of the substrate is being performed, or the substrate S is being transported, the operation is stopped.

As described above, according to the present embodiment, by virtue of providing a removal part 100 which removes the liquid material Q from the atmosphere inside the chamber 20 when a concentration of the solvent (hydrazine) of the liquid material Q within the atmosphere inside the chamber exceeds a predetermined threshold value, increase in the hydrazine concentration in the atmosphere can be suppressed. As a result, change in the coating environment can be suppressed.

The technical scope of the present invention is not limited to the above-described embodiment, but may be appropriately modified into various forms without departing from the spirit of the present invention. For example, in the above-described embodiment, the control part CONT stops all operations of the coating apparatus CTR when the value detected by the solvent concentration sensors SR1 to SR4 exceeds the second threshold value. However, the present invention is not limited to such a configuration. For example, after the control part CONT stops all operations, only the inert gas supplying step may be performed, so as to discharge hydrazine inside the chamber 20. When the hydrazine concentration inside the chamber 20 falls below the second threshold value as a result of discharging hydrazine, for example, the control part CONT may perform the removing step in the same manner as in the above-described embodiment.

In the aforementioned embodiment, the coating part CT has a configuration which uses a slit-type nozzle NZ, but the present invention is not limited thereto. For example, a center-dripping-type coating part or an ink jet coating part may be used. Alternatively, for example, the liquid material disposed on the substrate S may be diffused by using a squeezer or the like so as to be coated thereon.

Further, in the aforementioned embodiment, when a configuration in which the coating apparatus CTR is accommodated in one room is employed, a gas supply/exhaust part which adjusts the atmosphere inside the room may be provided. In such a case, hydrazine present in the atmosphere inside the room may be discharged using the gas supply/exhaust part, thereby more reliably suppressing change in the coating environment.

Further, with respect to the arrangement of the solvent concentration sensors, the present invention is not limited to the solvent concentration sensors SR1 to SR4 described in the aforementioned embodiment. For example, solvent concentration sensors (SR5 to SR12) may be disposed at positions shown with broken lines in FIG. 1 and FIG. 2.

More specifically, the solvent concentration sensor SR5 and the solvent concentration sensor SR6 are disposed at the treatment room 20a. The solvent concentration sensor SR5 is disposed between the liquid material supply part 33 and the waste liquid collection part 35. The solvent concentration sensor SR6 is disposed on the +X-side of the nozzle standby position 46 and the preliminary ejection part 44.

The solvent concentration sensor SR7 and the solvent concentration sensor SR8 are disposed outside the treatment room 20a. The solvent concentration sensor SR7 is disposed at a corner portion on the +Y-side of a −X-side face of the base BC. The solvent concentration sensor SR8 is disposed at a corner portion on the +X-side of a −Y-side face of the base BC.

Further, the solvent concentration sensor SR9 and the solvent concentration sensor SR10 are disposed at the treatment room 60a. The solvent concentration sensor SR9 is disposed on a −X-side, −Y-side corner of the platform 74. The solvent concentration sensor SR10 is disposed on a +X-side, +Y-side corner of the platform 74.

The solvent concentration sensor SR11 and the solvent concentration sensor SR12 are disposed outside the treatment room 60a, for example, on the floor FL. The solvent concentration sensor SR11 is disposed on the +Y-side wall portion of the base BB at a central portion in the X direction. The solvent concentration sensor SR12 is disposed on the −Y-side wall portion of the base BB at a central portion in the X direction. The configuration using solvent concentration sensors SR5 to SR12 is also just one example, and a configuration in which a solvent concentration sensor is disposed at another position may be employed.

In the aforementioned embodiment, explanation was given taking example of a configuration in which rollers are provided for transporting the substrate S. However, the present invention is not limited thereto. For example, a configuration in which a robot transport part is provided for the transportation may be employed. The robot transport part may be appropriately provided at any of the substrate loading/unloading part LU, the coating part CT, the vacuum drying part VD and the baking part BK.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A coating apparatus comprising:
a coating part which applies a liquid material containing an oxidizable metal and a solvent to a substrate,
a chamber having a coating space in which the coating part applies the liquid material to the substrate and a transport space into which the substrate is transported, and
a removal part which removes the liquid material from the atmosphere inside the chamber when a concentration of the solvent in the atmosphere inside the chamber exceeds a first threshold value.

2. The coating apparatus according to claim 1, which further comprises a detection part which detects the concentration of the solvent in the atmosphere inside the chamber.

3. The coating apparatus according to claim 1, wherein the removal part comprises a recovery part which recovers the removed liquid material.

4. The coating apparatus according to claim 3, wherein the recovery part further comprises a circulation path which returns the removed liquid material into the chamber.

5. The coating apparatus according to claim 1, wherein the removal part comprises a discharge part which discharges the solvent in the atmosphere inside the chamber.

6. The coating apparatus according to claim 1, wherein the removal part comprises a control device which controls the removal part to wait removing the liquid material until the coating part finishes treating the substrate having the liquid material applied thereto when the concentration of the solvent in the atmosphere inside the chamber exceeds the first threshold value.

7. The coating apparatus according to claim 6, wherein the control device stops the substrate which has finished being treated from being transported to the coating part.

8. The coating apparatus according to claim 6, wherein the control part controls the removal part to wait removing the liquid material until the coating part is moved to a maintenance position after the substrate has been finished being treated.

9. The coating apparatus according to claim 6, wherein the control device stops at least all treatments associated with coating of the liquid material when the concentration of the solvent in the atmosphere inside the chamber exceeds a second threshold value which is larger than the first threshold value.

10. The coating apparatus according to claim 1, wherein the coating part comprises a slit nozzle which ejects the liquid material.

11. A coating method comprising:
a coating step in which a liquid material containing an oxidizable metal and a solvent is applied to a substrate; and
a removing step in which the liquid material is removed from the atmosphere inside a chamber having a coating space where the coating part applies the liquid material to the substrate and a transport space into which the substrate is transported when a concentration of the solvent in the atmosphere inside the chamber exceeds a first threshold value.

12. The coating method according to claim 11, which further comprises a detection step in which the concentration of the solvent in the atmosphere inside the chamber is detected.

13. The coating method according to claim 11, wherein the removing step comprises a recovering step in which the removed liquid material is recovered.

14. The coating method according to claim 13, wherein the recovering step comprises a returning step in which the removed liquid material is returned into the chamber.

15. The coating method according to claim 11, wherein the removing step comprises a discharging step in which the solvent in the atmosphere inside the chamber is discharged.

16. The coating method according to claim 11, wherein the removing step waits removing the liquid material until the coating part finishes treating the substrate having the liquid material applied thereto when the concentration of the solvent in the atmosphere inside the chamber exceeds the first threshold value.

17. The coating method according to claim 16, wherein the removing step comprises stopping the substrate which has finished being treated from being transported to the coating part.

18. The coating method according to claim 16, wherein the removing step is performed after the coating part is moved to a maintenance position after the substrate has been finished being treated.

19. The coating method according to claim 11, wherein the removing step comprises stopping at least all treatments associated with coating of the liquid material when the concentration of the solvent in the atmosphere inside the chamber exceeds a second threshold value which is larger than the first threshold value.

20. The coating method according to claim 11, wherein the coating step comprises ejecting the liquid material from a slit nozzle.
